(19) United States
(12) Patent Application Publication
(10) Pub. No.: US 2013/0228921 A1
(43) Pub. Date: Sep. 5, 2013

(54) SUBSTRATE STRUCTURE AND FABRICATION METHOD THEREOF

(71) Applicants: Liang-Yi Hung, Taichung (TW); Yu-Cheng Pai, Taichung (TW); Wei-Chung Hsiao, Taichung (TW); Chun-Hsien Lin, Taichung (TW); Ming-Chen Sun, Taichung (TW)

(72) Inventors: Liang-Yi Hung, Taichung (TW); Yu-Cheng Pai, Taichung (TW); Wei-Chung Hsiao, Taichung (TW); Chun-Hsien Lin, Taichung (TW); Ming-Chen Sun, Taichung (TW)

(73) Assignee: SILICONWARE PRECISION INDUSTRIES CO., LTD., Taichung (TW)

(21) Appl. No.: 13/534,620

(22) Filed: Jun. 27, 2012

(30) Foreign Application Priority Data
Mar. 2, 2012 (TW) 101106927

(51) Int. Cl. H01L 23/485; H01L 21/768; H01L 21/60; H01L 23/488

(52) U.S. Cl. 257/738; 257/762; 438/614; 438/106; 257/E23.017; 257/E23.021; 257/E21.59; 257/E21.508

(57) ABSTRACT

A substrate structure includes a substrate body and a plurality of conductive pads formed on the substrate body and each having a first copper layer, a nickel layer, a second copper layer and a gold layer sequentially stacked. The thickness of the second copper layer is less than the thickness of the first copper layer. As such, the invention effectively enhances the bonding strength between the conductive pads and solder balls to be mounted later on the conductive pads, and prolongs the duration period of the substrate structure.

### BACKGROUND OF THE INVENTION

1. Field of the Invention

The present invention relates to substrate structures and fabrication methods thereof, and more particularly, to a substrate structure having solder balls for external electrical connection and a fabrication method thereof.

2. Description of Related Art

Ball grid array (BGA) semiconductor package structures have been developed to meet the trend of lighter, thinner, shorter and smaller electronic products. In such a BGA semiconductor package structure, a semiconductor chip is disposed on a surface of a substrate and electrically connected to the substrate through a plurality of bonding wires, and a plurality of solder balls are mounted on conductive pads of the other surface of the substrate, respectively, so as to electrically connect another electronic device such as a circuit board or another package structure.

FIGS. 1A and 1B are schematic cross-sectional views of a conductive pad in a conventional substrate structure (not shown).

Referring to FIG. 1A, the conductive pad has a copper layer 11, a nickel layer 12 and a gold layer 13 sequentially stacked on one another.

Referring to FIG. 1B, a solder flux 14 is coated on the gold layer 13 for attaching a solder ball 15 to the gold layer 13. Then, a reflow process is performed. Since the gold layer 13 is thin and diffuses quickly, the gold layer 13 is dissolved into the solder ball 15 during the reflow process. Further, a bonding layer 16 is formed between the solder ball 15 and the nickel layer 12 so as to bond the solder ball to the conductive pad. Therein, the bonding layer 16 contains nickel-tin alloy, thus leading to high thermal conductivity and low stress tolerance. Therefore, during a drop test, the solder ball may easily fall off from the conductive pad.

FIGS. 2A and 2B are schematic cross-sectional views of a conductive pad in another conventional substrate structure (not shown).

Referring to FIG. 2A, the conductive pad has a copper layer 21 and an OSP (Organic Solderability Preservative) layer 22 formed on the copper layer 21.

Referring to FIG. 2B, a solder flux 23 is coated on the OSP layer 22 for attaching a solder ball 24 to the OSP layer 22. Then, a reflow process is performed, during which the OSP layer 22 and the solder flux 23 are volatilized. The solder flux 23 facilitates to clean the outer portion of the copper layer 21 so as to form a bonding layer 25 between the solder ball 24 and the copper layer 21. Therein, the bonding layer 25 contains copper-tin alloy, thus leading to high stress tolerance and low thermal conductivity. Therefore, during a drop test, the solder ball is not easy to fall off.

However, compared with the gold layer 13, the OSP layer 22 can be easily oxidized and absorb moisture, thereby resulting in a short duration period. Therefore, the bonding reliability of the solder ball 24 is reduced, which results in a low product reliability.

Therefore, there is a need to provide a substrate structure and a fabrication method thereof so as to overcome the above-described drawbacks.

### SUMMARY OF THE INVENTION

Accordingly, the present invention provides a substrate structure, which comprises: a substrate body; and a plurality of conductive pads formed on the substrate body and each having a first copper layer, a nickel layer, a second copper layer and a gold layer sequentially stacked on one another, wherein the thickness of the second copper layer is less than the thickness of the first copper layer.

The present invention further provides another substrate structure, which comprises: a substrate body; a plurality of conductive pads formed on the substrate body and each having a copper layer and a nickel layer formed on the copper layer; a bonding layer formed on the conductive pads; and a plurality of solder balls disposed on the bonding layer of the conductive pads, respectively.

The present invention further provides a fabrication method of a substrate structure, which comprises the steps of: sequentially forming a first copper layer, a nickel layer, a second copper layer and a gold layer on a substrate body, wherein the thickness of the second copper layer is less than the thickness of the first copper layer.

The present invention further provides a substrate structure, which comprises: a substrate body; and a plurality of conductive pads formed on the substrate body and each having a copper layer, a nickel-copper mixed layer and a gold layer sequentially stacked on one another, wherein, in the nickel-copper mixed layer, the content of copper is less than the content of nickel.

The present invention further provides another substrate structure, which comprises: a substrate body; a plurality of conductive pads formed on the substrate body and each having a copper layer and a nickel-copper mixed layer formed on the copper layer, wherein, in the nickel-copper mixed layer, the content of copper is less than the content of nickel; a bonding layer formed on the conductive pads; and a plurality of solder balls disposed on the bonding layer of the conductive pads, respectively.

The present invention further provides another fabrication method of a substrate structure, which comprises the steps of: forming a plurality of conductive pads on a substrate body, wherein each of the conductive pads has a copper layer; and sequentially forming a nickel-copper mixed layer and a gold layer on the copper layer, wherein, in the nickel-copper mixed layer, the content of copper is less than the content of nickel.

According to the present invention, each of the conductive pads merely contains little copper besides nickel and gold such that the bonding layer between the conductive pad and the corresponding solder balls is mainly comprised of Cu₆Sn₅ instead of Ni₃Sn₄ as in the prior art, thereby achieving a preferred bonding performance. Further, the gold layer on each of the conductive pads retards oxidation and moisture absorption so as to prolong the duration period of the substrate structure.

### BRIEF DESCRIPTION OF DRAWINGS

FIGS. 1A and 1B are schematic cross-sectional views of a conductive pad in a conventional substrate structure;

FIGS. 2A and 2B are schematic cross-sectional views of a conductive pad in another conventional substrate structure;

FIGS. 3A to 3E are schematic cross-sectional views showing a substrate structure and a fabrication method thereof according to a first embodiment of the present invention; and

FIGS. 4A to 4D are schematic cross-sectional vies showing a substrate structure and a fabrication method thereof according to a second embodiment of the present invention.

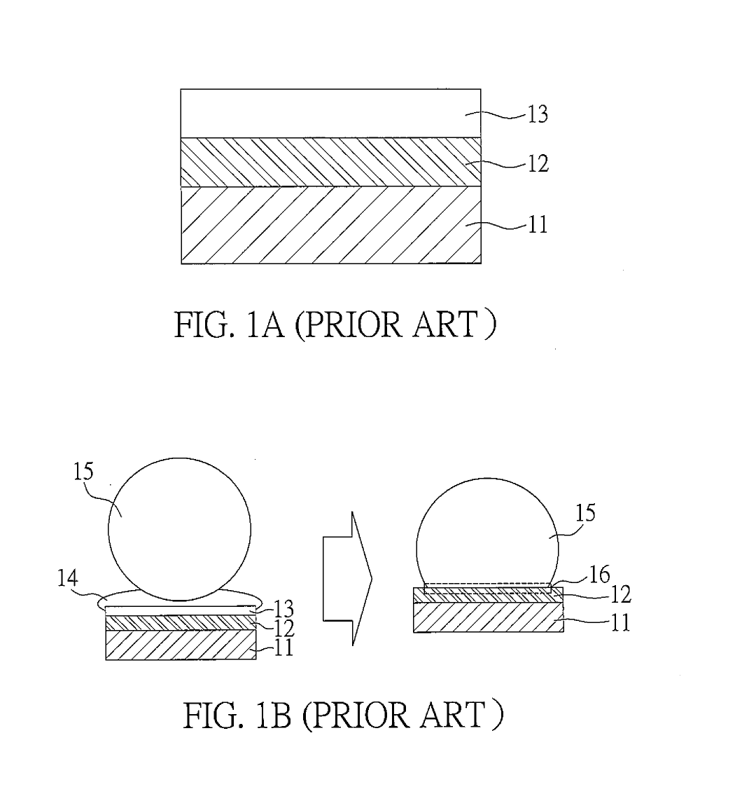

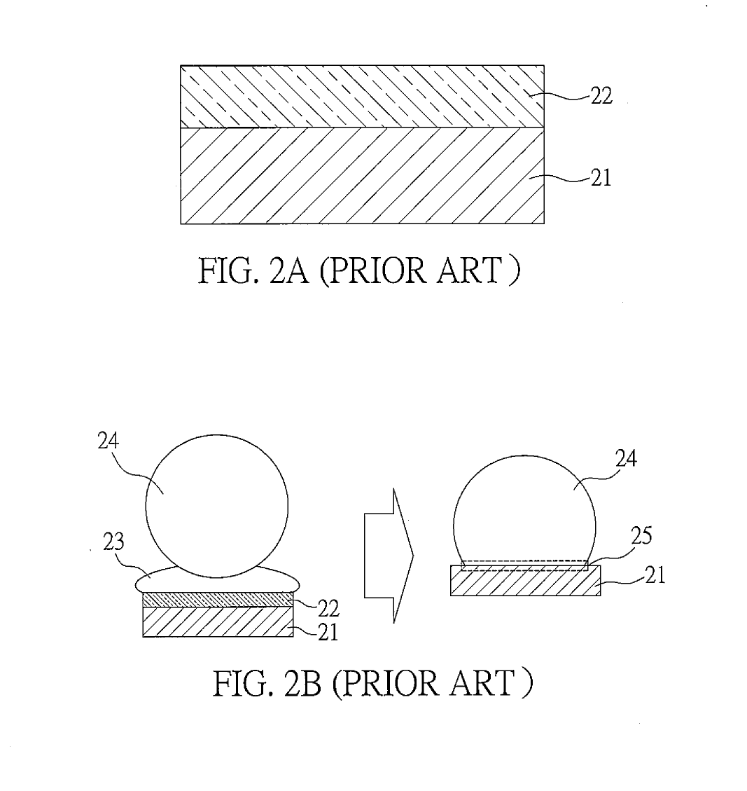

### DETAILED DESCRIPTION OF PREFERRED EMBODIMENTS

The following illustrative embodiments are provided to illustrate the disclosure of the present invention, these and other advantages and effects can be apparent to those in the art after reading this specification.

It should be noted that all the drawings are not intended to limit the present invention. Various modification and variations can be made without departing from the spirit of the present invention. Further, terms such as “one”, “on”, “top” etc. are merely for illustrative purpose and should not be construed to limit the scope of the present invention.

### First Embodiment

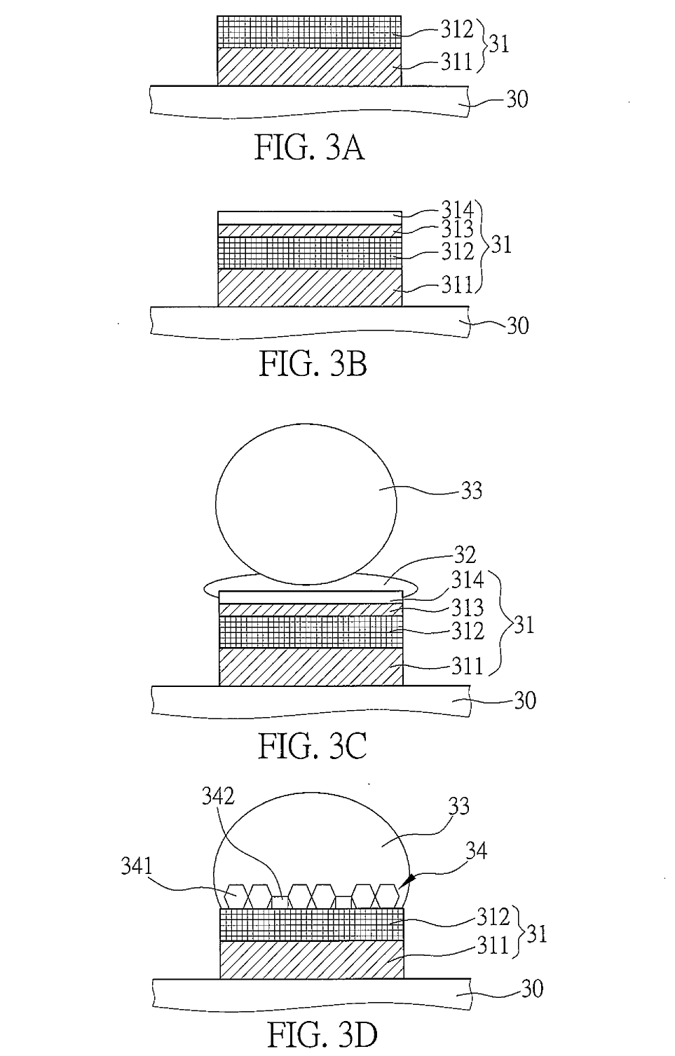

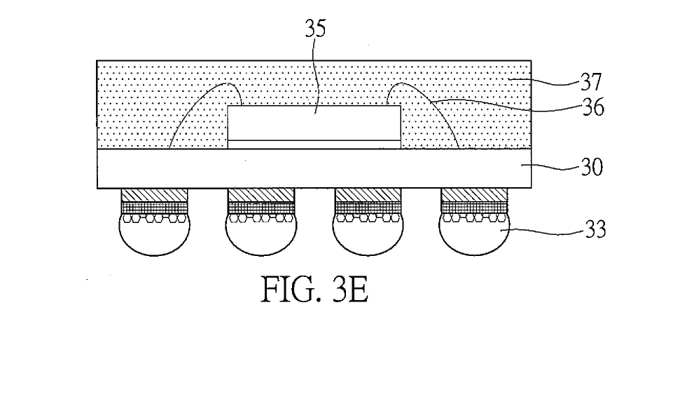

FIGS. 3A to 3E are schematic cross-sectional views showing a substrate structure and a fabrication method thereof according to a first embodiment of the present invention.

Referring to FIG. 3A, a substrate body 30 is provided and a plurality of conductive pads 31 (only one conductive pad is illustrated in the drawing) are formed on the substrate body 30. Each of the conductive pads 31 has a first copper layer 311 and a nickel layer 312 formed on the first copper layer 311.

Referring to FIG. 3B, a second copper layer 313 and a gold layer 314 are sequentially formed on the nickel layer 312. The second copper layer 313 has a thickness less than that of the first copper layer 311.

Referring to FIG. 3C, a solder flux 32 is formed on the gold layer 314 so as for a solder ball 33 to be mounted thereon.

Referring to FIG. 3D, a reflow process is performed so as to volatilize the solder flux 32 and dissolve the gold layer 314 into the solder ball 33 and also dissolve the second copper layer 313, thereby forming a bonding layer 34 between the solder ball 33 and the nickel layer 312. The bonding layer 34 is comprised of Cu₆Sn₅ 341 and Ni₃Sn₄ 342, and the content of Ni₃Sn₄ 342 is less than the content of Cu₆Sn₅ 341. It should be noted that the bonding layer 34 is shown in an enlarged view for purpose of illustration and not intended to limit the present invention.

Referring to FIG. 3E, a semiconductor chip 35 is disposed on the substrate body 30 opposite to the conductive pads 31 and electrically connected to the substrate body 30 through a plurality of bonding wires 36. Further, an encapsulant 37 is formed to encapsulate the chip 35 and the bonding wires 36.

The present invention further provides a substrate structure, which has: a substrate body 30, and a plurality of conductive pads 31 formed on the substrate body 30 and each having a first copper layer 311, a nickel layer 312, a second copper layer 313 and a gold layer 314 sequentially stacked on one another. Therein, the second copper layer 313 has a thickness less than that of the first copper layer 311.

The above-described substrate structure further has a solder flux 32 applied on the gold layer 314 and a plurality of solder balls 33 disposed on the solder flux 32.

The present invention further provides another substrate structure, which has: a substrate body 30; a plurality of conductive pads 31 formed on the substrate body 30 and each having a first copper layer 311 and a nickel layer 312 formed on the first copper layer 311; a bonding layer 34 formed on the conductive pads 31; and a plurality of solder balls 33 disposed on the bonding layer 34 of the conductive pads 31, respectively.

The bonding layer is comprised of Cu₆Sn₅ 34 land Ni₃Sn₄ 342, and the content of Ni₃Sn₄ 342 is less than the content of Cu₆Sn₅ 341.

### Second Embodiment

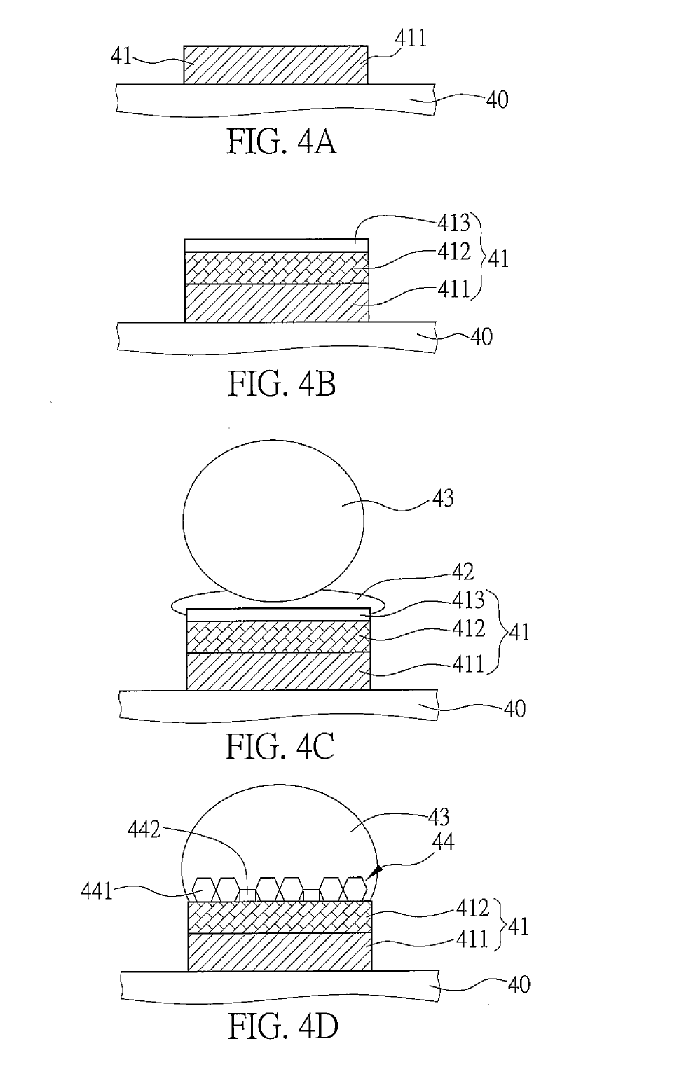

FIGS. 4A to 4D are schematic cross-sectional views showing a substrate structure and a fabrication method thereof according to a second embodiment of the present invention.

Referring to FIG. 4A, a substrate body 40 is provided and a plurality of conductive pads 41 are formed on the substrate body 40. Each of the conductive pads 41 has a copper layer 411.

Referring to FIG. 4B, a nickel-copper mixed layer 412 and a gold layer 413 are sequentially formed on the copper layer 411. In the nickel-copper mixed layer 412, the content of copper is less than the content of nickel.

Referring to FIG. 4C, a solder flux 42 is formed on the gold layer 413 so as for a plurality of solder balls 43 to be mounted thereon. Referring to FIG. 4D, a reflow process is performed to volatilize the solder flux 42 and dissolve the gold layer 413 into the solder ball 43, thus forming a bonding layer 44 between the solder ball 43 and the nickel-copper mixed layer 412. The bonding layer 44 is comprised of Cu₆Sn₅ 441 and Ni₃Sn₄ 442, and the content of Ni₃Sn₄ 442 is less than the content of Cu₆Sn₅ 441. It should be noted that the bonding layer 44 is shown in an enlarged view for purpose of illustration and not intended to limit the present invention.

In the present embodiment, a die attaching process and a packaging process similar to the first embodiment can further be performed. Since the processes are well known in the art, detailed description thereof is omitted herein.

The present invention further provides a substrate structure, which has: a substrate body 40, and a plurality of conductive pads 41 formed on the substrate body 40 and each having a copper layer 411, a nickel-copper mixed layer 412 and a gold layer 413 sequentially stacked on one another. In the nickel-copper mixed layer 412, the content of copper is less than the content of nickel.

The substrate structure can further have a solder flux 42 applied on the gold layer 413 and a plurality of solder balls 43 disposed on the solder flux 42.

The present invention further provides another substrate structure, which has: a substrate body 40; a plurality of conductive pads 41 formed on the substrate body 40 and each having a copper layer 411 and a nickel-copper mixed layer 412 formed on the copper layer 411, wherein in the nickel-copper mixed layer 412, the content of copper is less than the content of nickel; a bonding layer 44 formed on the conductive pads 41; and a plurality of solder balls 43 disposed on the bonding layer 44 of the conductive pads 41, respectively.

The bonding layer 44 is comprised of Cu₆Sn₅ 441 and Ni₃Sn₄ 442 and the content of Ni₃Sn₄ 442 is less than the content of Cu₆Sn₅ 441.

According to the present invention, each of the conductive pads merely contains little copper besides nickel and gold such that the bonding layer between the conductive pad and the corresponding solder ball is mainly comprised of Cu₆Sn₅ instead of Ni₃Sn₄ as in the prior art, thereby achieving a preferred bonding performance. Further, the gold layer on each of the conductive pads retards oxidation and moisture absorption so as to prolong the duration period of the substrate structure.

The above-described descriptions of the detailed embodiments are only to illustrate the preferred implementation according to the present invention, and it is not to limit the scope of the present invention. Accordingly, all modifications and variations completed by those with ordinary skill in the art should fall within the scope of present invention defined by the appended claims.

What is claimed is:

1. A substrate structure, comprising:
a substrate body; and
a plurality of conductive pads formed on the substrate body and each having a first copper layer, a nickel layer, a second copper layer and a gold layer sequentially stacked, wherein the second copper layer is less in thickness than the first copper layer.

2. The structure of claim 1, further comprising a solder flux applied on the gold layer.

3. The structure of claim 1, further comprising a semiconductor chip disposed on and electrically connected to the substrate body.

4. A substrate structure, comprising:
a substrate body;
a plurality of conductive pads formed on the substrate body and each having a copper layer and a nickel layer formed on the copper layer;
a bonding layer formed on the conductive pads; and
a plurality of solder balls disposed on the bonding layer of the conductive pads, respectively.

5. The structure of claim 4, wherein the bonding layer is comprised of Cu₆Sn₅ and Ni₃Sn₄, and wherein the Ni₃Sn₄ is less in content than the Cu₆Sn₅.

6. The structure of claim 4, further comprising a semiconductor chip disposed on and electrically connected to the substrate body.

7. A fabrication method of a substrate structure, comprising the steps of:
providing a substrate body; and
sequentially forming a first copper layer, a nickel layer, a second copper layer and a gold layer on the substrate body, wherein the second copper layer is less in thickness than the first copper layer.

8. The method of claim 7, further comprising forming a solder flux on the gold layer.

9. The method of claim 8, further comprising mounting a plurality of solder balls on the solder flux and performing a reflow process so as to volatilize the solder flux and dissolve the gold layer into the solder balls and dissolve the second copper layer, thereby forming a bonding layer between the solder balls and the nickel layer.

10. The method of claim 9, wherein the bonding layer is comprised of Cu₆Sn₅ and Ni₃Sn₄, and wherein the Ni₃Sn₄ is less in content than the Cu₆Sn₅.

11. The method of claim 7, further comprising disposing a semiconductor chip on the substrate body and electrically connecting the semiconductor chip to the substrate body.

12. A substrate structure, comprising:
a substrate body; and
a plurality of conductive pads formed on the substrate body and each having a copper layer, a nickel-copper mixed layer and a gold layer sequentially stacked, wherein, in the nickel-copper mixed layer, the copper is less in content than the nickel.

13. The structure of claim 12, further comprising a solder flux applied on the gold layer.

14. The structure of claim 12, further comprising a semiconductor chip disposed on and electrically connected to the substrate body.

15. A substrate structure, comprising:
a substrate body;
a plurality of conductive pads formed on the substrate body and each having a copper layer and a nickel-copper mixed layer formed on the copper layer, wherein, in the nickel-copper mixed layer, the copper is less in content than the nickel;
a bonding layer formed on the conductive pads; and
a plurality of solder balls disposed on the bonding layer of the conductive pads, respectively.

16. The structure of claim 15, wherein the bonding layer is comprised of Cu₆Sn₅ and Ni₃Sn₄, and wherein the Ni₃Sn₄ is less in content than the Cu₆Sn₅.

17. The structure of claim 15, further comprising a semiconductor chip disposed on and electrically connected to the substrate body.

18. A fabrication method of a substrate structure, comprising the steps of:
forming a plurality of conductive pads on a substrate body, wherein each of the conductive pads has a copper layer; and
sequentially forming a nickel-copper mixed layer and a gold layer on the copper layer, wherein, in the nickel-copper mixed layer, the copper is less in content than the nickel.

19. The method of claim 18, further comprising forming a solder flux on the gold layer.

20. The method of claim 19, further comprising mounting a plurality of solder balls on the solder flux and performing a reflow process so as to volatilize the solder flux and dissolve the gold layer into the solder balls, thereby forming a bonding layer between the solder balls and the nickel-copper mixed layer.

21. The method of claim 20, wherein the bonding layer is comprised of Cu₆Sn₅ and Ni₃Sn₄, and wherein the Ni₃Sn₄ is less in content than the Cu₆Sn₅.

22. The method of claim 18, further comprising disposing a semiconductor chip on the substrate body and electrically connecting the semiconductor chip to the substrate body.
